(19) United States
(12) Patent Application Publication
(10) Pub. No.: US 2008/0102633 A1
(43) Pub. Date: May 1, 2008

(54) Method for manufacturing semiconductor device and semiconductor device

(75) Inventor: Yusuke Matsuzawa, Chino-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/978,735

(22) Filed: Oct. 30, 2007

(30) Foreign Application Priority Data
Nov. 1, 2006 (JP) 2006-297450
Oct. 3, 2007 (JP) 2007-259512

(51) Int. Cl. H01L 21/302

(52) U.S. Cl. 438/691; 257/E21.214

(57) ABSTRACT

A method for manufacturing a semiconductor device includes: a first step for successively staking on a semiconductor substrate a first semiconductor layer, a second semiconductor layer and a third semiconductor layer; a second step for forming on the semiconductor substrate a first groove passing through the third semiconductor layer, the second semiconductor layer and the first semiconductor layer by partially etching the third semiconductor layer, the second semiconductor layer and the first semiconductor layer successively; a third step for forming on the entire surface of the upper side of the semiconductor substrate a carrier film to fill the first groove and cover the third semiconductor layer; a fourth step for exposing the third semiconductor layer by partially etching the carrier film including its site covering the third semiconductor layer; a fifth step for forming a second groove by successively etching the third semiconductor layer, the second semiconductor layer and the first semiconductor layer, the etching starting from the exposed site of the third semiconductor layer in the fourth step; a sixth step for forming a first cavity by etching the first semiconductor layer exposed on a lateral surface of the second groove; a seventh step for forming a second cavity by etching the third semiconductor layer exposed on a lateral surface of the second groove; and an eighth step for forming, by applying heat to the semiconductor substrate, a first thermally-oxidized film in the first cavity and a second thermally-oxidized film in the second cavity.

The entire disclosure of Japanese Patent Application Nos: 2006-297450, filed Nov. 1, 2006 and 2007-259512, filed Oct. 3, 2007 are expressly incorporated by reference herein.

### BACKGROUND OF THE INVENTION

1. Technical Field

The present invention relates to a method for manufacturing a semiconductor device, in particular to a technique according to which space is prevented from remaining in an interface between thermally-oxidized films respectively growing upwards and downwards.

2. Related Art

Filed-effect transistors formed on SOI substrates have been attracting attention because of its usability in the terms of easiness in isolation, freedom from latch-up, reduced source/drain junction capacitance etc. Among those field-effect transistors, completely-depleted SOI transistors are capable of operating at a high speed with reduced power consumption and are easily driven with low voltage, so there has been a marked increase of research with a view to allowing SOI transistors to operate in a completely-depleted mode. As SOI substrates, Separation by Implanted Oxygen (SIMOX) substrates or laminated substrates, for example, have been used. However, those substrates each require special manufacturing method and cannot be fabricated by using common CMOS process.

Against such a background, there is known a Separation by Bonding Silicon Island (SBSI) method, according to which a SOI structure is fabricated from an ordinary bulk silicon by using common CMOS process (see T. Sakai et al. “Separation by Bonding Si Islands (SBSI) for LST Application”, Second International SiGe Technology and Device Meeting, Meeting Abstract, pp. 230-231, May (2004)). Hereinafter, the SBSI method will be described with reference to drawings.

FIG. 8A through FIG. 10B are views each illustrating a method for manufacturing a semiconductor device according to the prior art. FIG. 8A, FIG. 9A and FIG. 10A are plan views, and FIG. 8B, FIG. 9B and FIG. 10B are sectional views respectively taken along with the lines X8-X8′ of FIG. 8A, X9-X9′ of FIG. 9A and X10-X10′ of FIG. 10A.

As shown in FIG. 8A and FIG. 8B, first, a silicon germanium (SiGe) layer 111 and a Si layer 113 are successively formed on a silicon (Si) substrate 101. Then, a groove h′1 for carrier is provided thereon. The Si layer 113 and the SiGe layer 111 are formed by using epitaxy and the groove h′1 for carrier is formed by using dry etching. Next, a carrier film is formed over the entire surface of the Si substrate 101. After that, the carrier film is subjected to dry etching so that a carrier 122 shown in FIG. 9A and FIG. 9B is formed. Further, Si layer 113/SiGe layer 111 exposed from the bottom of the carrier 122 are also subjected to dry etching. In this state, the SiGe layer 111 is subjected to etching by using solution of fluorinated acid and nitric acid applied in the direction indicated by the arrow shown in FIG. 9A. Then, a cavity 125 is formed under the Si layer 113 while the Si layer 113 is hanged from the carrier 122.

Next, as shown in FIG. 10A and FIG. 10B, the Si substrate 101 is subjected to thermal oxidation so that a SiO₂ film 131 is formed in the cavity 125 (BOX oxidation process). As thus described above, a SOI structure made up of the SiO₂ film 131 and the Si layer 113 is formed on a bulk wafer. After the formation of the SOI structure, a SiO₂ film (not shown) is formed over the entire surface of the Si substrate 101 by using CVD. Then, the SiO₂ film and the carrier 122 are planarized by using CMP. Further, the surface of the Si layer 113 is exposed by carrying out wet etching using HF type solution (i.e. HF etching).

The BOX oxidation process is an important element of the above-mentioned SBSI method. Currently, in order to form a BOX layer, the SiO₂ films 131a and 131b grown respectively upwards and downwards are brought into close contact with each other in the vicinity of their meeting point, which is spaced equally from both films, by using oxidation treatment at the temperature of 1000° C. for an hour.

However, as shown in FIG. 11, when the section after the oxidation is observed by using a Scanning Electron Microscopy (SEM), there was a case in which both SiO₂ films respectively grown upwards and downwards are not in close contact with each other. This is caused by the warpage in the Si layer. The grown SiO₂ films themselves have enough film thickness so as to adhere to each other; however, the Si layer is warped upwardly in a convex manner, so there may be a case in which space remains at the center, in which the warpage is larger, between the SiO₂ films grown upwards and downwards. When in this state the following steps of exposing active surface by using buffered HF (BHF) etching and of washing of fluorinated acid are performed, there arises a fear in that BHF may enter the space, resulting in unintended etching of the SiO₂ film and falling off of the Si layer from the Si substrate.

With regard to this point, from the search results obtained so far, the inventors of the present invention have come to the assumption that the warpage in the Si layer during the BOX oxidation process would occur in the successive phenomena shown in FIG. 12A through FIG. 12D. To be more specific, as shown in FIG. 12A and FIG. 12B, the laminated structure of carrier 122/the Si layer 113, which is flat at a room temperature, becomes at first downwardly convex at an ascended temperature. In this case, the difference in the coefficients of thermal expansion between the SiO₂ constituting the carrier 122 and Si (Si: 4.15 E-6 /K, SiO₂: 0.55 E-6/K) is deemed to have a great influence on that. On the contrary, as shown in FIG. 12C, when the temperature further ascends and especially exceeds 960° C., the carrier 122 covering the Si layer 113 becomes viscous to flow (viscous flow), so the warpage is resolved and the Si layer 113 becomes temporally flat again. In this state, the thermal oxidation of the Si layer 113 further advances. With the completion of the oxidation treatment, the temperature now begins to descend. With the descended temperature shown in FIG. 12D, there occurs no viscous flow in the carrier 122, so the difference of the coefficients of thermal expansion begins to have influence again. As a result, the Si layer 113 becomes disadvantageously upwardly convex.

### SUMMARY

An advantage of the present invention is to provide a method for manufacturing a semiconductor device, according to which space can be prevented from remaining in an interface between the thermally-oxidized films respectively growing upwards and downwards.

[Invention 1] according to a first aspect of the invention, a method for manufacturing a semiconductor device includes: successively stacking on a semiconductor substrate a first semiconductor layer, a second semiconductor layer and a third semiconductor layer; forming a first groove on the semiconductor substrate passing through the third semiconductor layer, the second semiconductor layer and the first semiconductor layer by partially etching the third semiconductor layer, the second semiconductor layer and the first semiconductor layer successively; forming a carrier film over the entire surface of the semiconductor substrate to fill the first groove and cover the third semiconductor layer; forming a carrier that supports the second semiconductor layer with its upper part being covered by partially etching the carrier film; forming a second groove that makes the lateral surface of the third semiconductor layer and the lateral surface of the first semiconductor layer to be exposed by successively etching the third semiconductor layer, the second semiconductor layer and the first semiconductor layer exposed downwards from the carrier; forming a first cavity between the semiconductor substrate and the second semiconductor layer and a second cavity between the second semiconductor layer and the carrier by etching the first semiconductor layer and the third semiconductor layer through the intermediation of the second groove under such conditions that the first semiconductor layer and the third semiconductor layer are more easily etched than the second semiconductor layer; and forming a first thermally-oxidized film in the first cavity and a second thermally-oxidized film in the second cavity by applying heat to the semiconductor substrate. Here, the step for forming the first thermally-oxidized film in the first cavity is also referred to as a BOX oxidation process.

According to the first aspect of the invention, the method includes: a first step for successively staking on a semiconductor substrate a first semiconductor layer, a second semiconductor layer and a third semiconductor layer; a second step for forming on the semiconductor substrate a first groove passing through the third semiconductor layer, the second semiconductor layer and the first semiconductor layer by partially etching the third semiconductor layer, the second semiconductor layer and the first semiconductor layer successively; a third step for forming on the entire surface of the upper side of the semiconductor substrate a carrier film to fill the first groove and cover the third semiconductor layer; a fourth step for exposing the third semiconductor layer by partially etching the carrier film including its site covering the third semiconductor layer; a fifth step for forming a second groove by successively etching the third semiconductor layer, the second semiconductor layer and the first semiconductor layer, the etching starting from the exposed site of the third semiconductor layer in the fourth step; a sixth step for forming a first cavity by etching the first semiconductor layer exposed on a lateral surface of the second groove; a seventh step for forming a second cavity by etching the third semiconductor layer exposed on a lateral surface of the second groove; and an eighth step for forming, by applying heat to the semiconductor substrate, a first thermally-oxidized film in the first cavity and a second thermally-oxidized film in the second cavity. In this case, it is preferable that the sixth step and the seventh steps be performed at the same time.

According to such the method, it was possible to suppress the warpage in the second semiconductor layer at the time of forming the first thermally-oxidized film and to prevent space from remaining in the interface between the first thermally-oxidized films growing in the cavity respectively upwards and downwards. As a result, the etchant was prevented from entering the above-mentioned interface at the time of removal of the carrier, so it was possible to prevent the second semiconductor layer from falling off from the semiconductor substrate.

According to the assumption of the inventors of the invention, the reason of achieving such the effects is that at the time of the BOX oxidation process the upper and lower structures relative to the second semiconductor layer (in the vicinity of the second semiconductor layer) becomes substantially the same. The coefficients of thermal expansion of the first and second thermally-oxidized films are substantially the same, so it is deemed that during temperature ascending or descending period of the BOX oxidization the external force to be exerted from the first thermally-oxidized film onto the lower surface of the second semiconductor layer and the external force to be exerted from the second thermally-oxidized film onto the upper surface of the second semiconductor layer are almost balanced with each other. Further, it is deemed that the adhesion of the second thermally-oxidized film and the carrier is not so high, since the second thermally-oxidized film grows from the second semiconductor layer towards the carrier, so that the force involved in expansion or contract of the carrier is hardly transmitted to the second semiconductor layer.

[Invention 2] According to a second aspect of the invention, the method for manufacturing a semiconductor device further includes in addition to the first aspect of the invention: stacking an insulating layer on the entire surface of the semiconductor layer after the formation of the first thermally-oxidized film and the second thermally-oxidized film; and removing the insulating layer from the second semiconductor layer by applying at least CMP treatment to the insulating layer, the second thermally-oxidized film on the second semiconductor layer serving as a stopper for the CMP treatment. According to such the method, it is possible to prevent the surface of the second semiconductor layer from being scratched due to the CMP treatment.

According to the second aspect of the invention, the method for manufacturing a semiconductor device further includes: a ninth step for staking on the entire surface of the upper side of the semiconductor substrate an insulating layer after the formation of the first thermally-oxidized film and the second thermally-oxidized film; and a tenth step for removing the insulating layer and the carrier film on the upper side of the semiconductor substrate by applying at least CMP treatment to the insulating layer, the second thermally-oxidized layer serving as a stopper for the CMP treatment.

[Invention 3] According to a third aspect of the invention, the method for manufacturing a semiconductor device further includes in addition to the first aspect of the invention: stacking the third semiconductor layer the third semiconductor layer is formed relatively thicker so that space can be preserved between the upper surface of the second thermally-oxidized film and the carrier in the following steps even after the formation of the first thermally-oxidized film and the second thermally-oxidized film.

According to the third aspect of the invention, in the method for manufacturing a semiconductor device of the first aspect of the invention, the thickness of the third semiconductor layer formed in the first step is thicker than the thickness of the second thermally-oxidized film formed in the eighth step.

In this case, space is preserved between the upper surface of the second thermally-oxidized film and the carrier throughout the BOX oxidation process. Therefore, the influence of expansion and contraction of the carrier can be weakened through the intermediation of the space above described. As a result, it becomes possible to further suppress the warpage in the second semiconductor layer.

[Invention 4] According to a fourth aspect of the invention, the method for manufacturing a semiconductor device further includes in addition to the first aspect: forming a single-crystal silicon germanium (SiGe) layer by using epitaxy to be both the first semiconductor layer and the third semiconductor layer, and forming a single-crystal silicon (Si) layer by using epitaxy to be the second semiconductor layer.

In this case, it is possible to prevent space from remaining in the interface between the SiO₂ films growing respectively upwards and downwards in the first cavity, so the falling off of the Si layer from the semiconductor substrate can be prevented. Therefore, the SOI structure made up of Si/SiO₂ can be fabricated with a high yield.

[Invention 5] According to a fifth aspect of the invention, a semiconductor device fabricated by using the method for manufacturing a semiconductor device according to the first aspect of the invention, includes: the second thermally-oxidized film grown from the second semiconductor layer having function for preventing the second semiconductor layer from being deformed convex as described above or serving as a stopper for the CMP treatment.

### BRIEF DESCRIPTION OF THE DRAWINGS

The invention will be described with reference to the accompanying drawings, wherein like numbers reference like elements.

FIG. 1A is a view illustrating one of the successive steps of a semiconductor device according to an embodiment of the invention.

FIG. 1B is a view illustrating one of the successive steps of a semiconductor device according to the embodiment of the invention.

FIG. 2A is a view illustrating one of the successive steps of a semiconductor device according to the embodiment of the invention.

FIG. 2B is a view illustrating one of the successive steps of a semiconductor device according to the embodiment of the invention.

FIG. 3A is a view illustrating one of the successive steps of a semiconductor device according to the embodiment of the invention.

FIG. 3B is a view illustrating one of the successive steps of a semiconductor device according to the embodiment of the invention.

FIG. 4A is a view illustrating one of the successive steps of a semiconductor device according to the embodiment of the invention.

FIG. 4B is a view illustrating one of the successive steps of a semiconductor device according to the embodiment of the invention.

FIG. 5A is a view illustrating one of the successive steps of a semiconductor device according to the embodiment of the invention.

FIG. 5B is a view illustrating one of the successive steps of a semiconductor device according to the embodiment of the invention.

FIG. 6A is a view illustrating one of the successive steps of a semiconductor device according to the embodiment of the invention.

FIG. 6B is a view illustrating one of the successive steps of a semiconductor device according to the embodiment of the invention.

FIG. 6C is a view illustrating one of the successive steps of a semiconductor device according to the embodiment of the invention.

FIG. 7A is a view illustrating a case in which a SiGe layer 15 is formed so as to be relatively thicker.

FIG. 7B is a view illustrating the case in which a SiGe layer 15 is formed so as to be relatively thicker.

FIG. 8A is a view illustrating one of the successive steps of a semiconductor device according to the prior art.

FIG. 8B is a view illustrating one of the successive steps of a semiconductor device according to the prior art.

FIG. 9A is a view illustrating one of the successive steps of a semiconductor device according to the prior art.

FIG. 9B is a view illustrating one of the successive steps of a semiconductor device according to the prior art.

FIG. 10A is a view illustrating one of the successive steps of a semiconductor device according to the prior art.

FIG. 10B is a view illustrating one of the successive steps of a semiconductor device according to the prior art.

FIG. 11 is a view showing a problem in the case of the prior art.

FIG. 12A is one of the successive views showing the mechanism for occurrence of warpage in a Si layer.

FIG. 12B is one of the successive views showing the mechanism for occurrence of warpage in a Si layer.

FIG. 12C is one of the successive views showing the mechanism for occurrence of warpage in a Si layer.

FIG. 12D is one of the successive views showing the mechanism for occurrence of warpage in a Si layer.

### DESCRIPTION OF EXEMPLARY EMBODIMENTS

Hereinafter, an embodiment of the invention will be described with reference to the attached drawings.

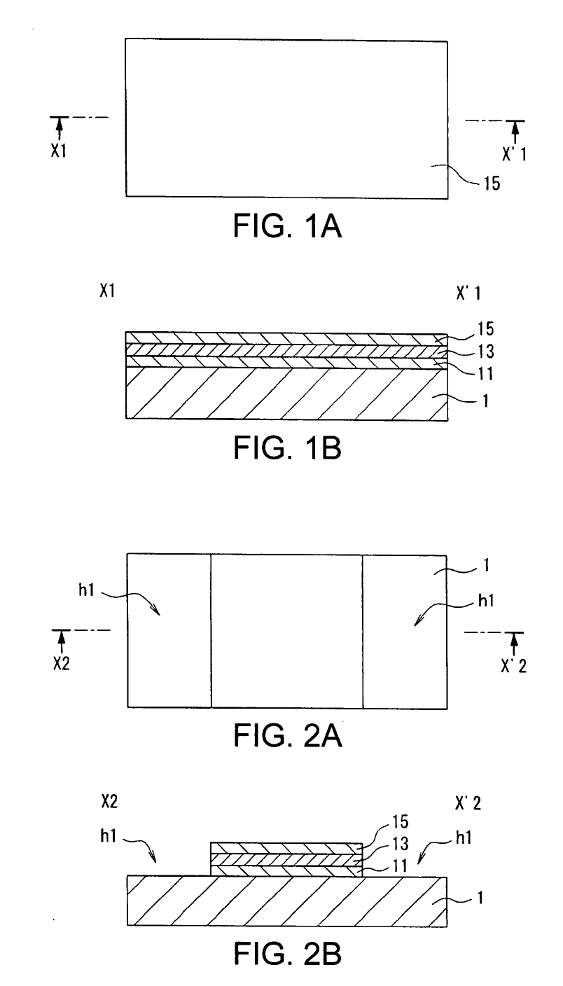

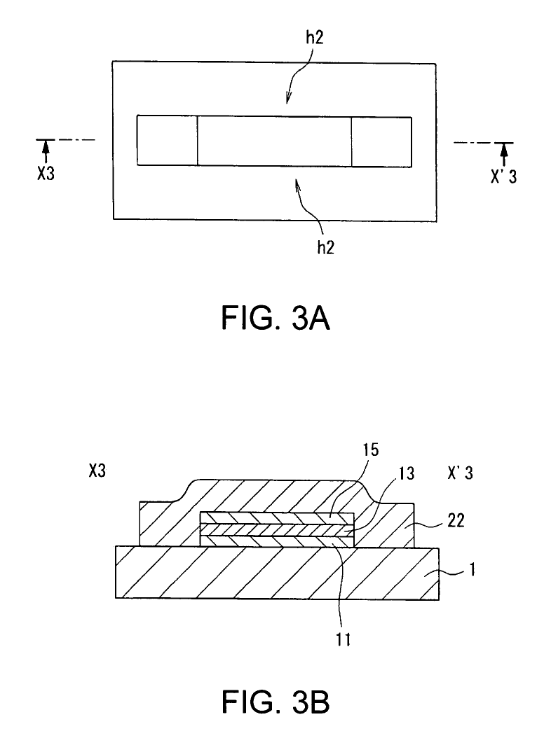

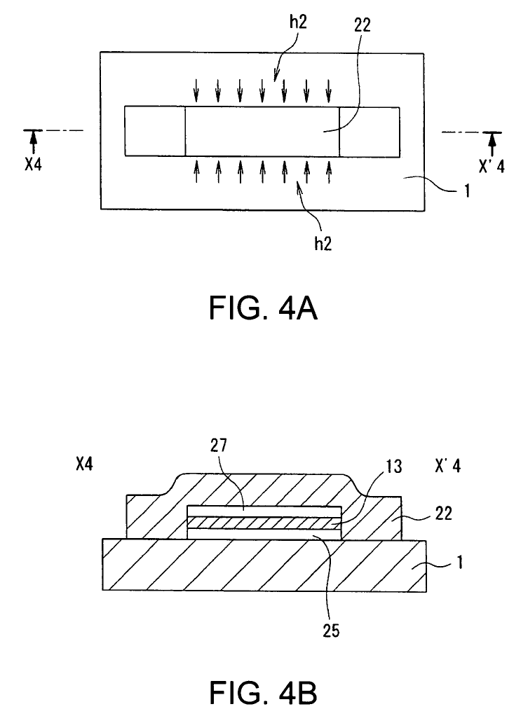

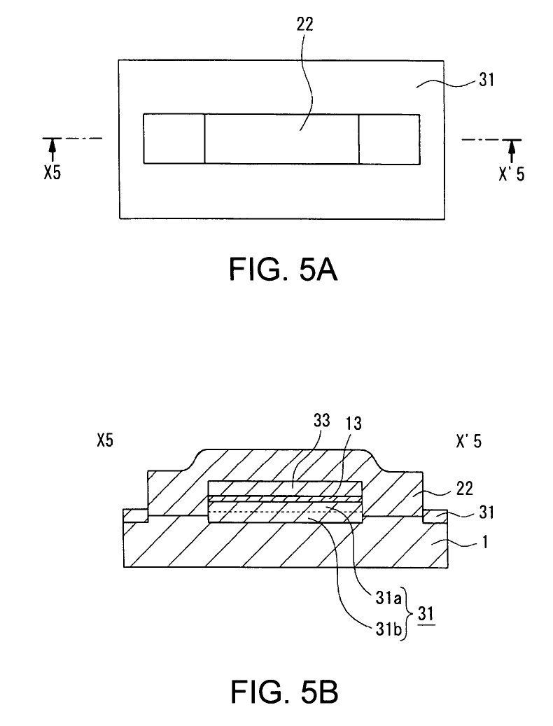

FIG. 1A through FIG. 5B are views each illustrating a method of manufacturing a semiconductor device according to the embodiment of the invention. FIG. 1A, FIG. 2A, FIG. 3A, FIG. 4A and FIG. 5A are plan views, FIG. 1B, FIG. 2B, FIG. 3B, FIG. 4B and FIG. 5B are sectional views respectively taken along with the lines X1-X1′ of FIG. 1A, X2-X2′ of FIG. 2A, X3-X3′ of FIG. 3A, X4-X4′ of FIG. 4A and X5-X5′ of FIG. 5A.

As shown in FIG. 1A and FIG. 1B, a silicon buffer (Si-buffer) not shown is formed on a silicon (Si) substrate 1. On the silicon buffer, there is formed a first silicon germanium (SiGe) layer 11, on which a Si layer 13 is formed. Then, a second SiGe layer 15 is formed on the Si layer 13. The Si layer 1 is a bulk wafer. Further, the Si-buffer layer, the SiGe layer 11, the Si layer 13 and the SiGe layer 15 are formed successively by using epitaxy. The SiGe layer 11 and the SiGe layer 15 are made to have, for example, the same thickness.

Next, as shown in FIG. 2A and FIG. 2B, the SiGe layer 15, the Si layer 13, the SiGe layer 11 and the Si-buffer layer (not shown) are partially etched by using photolithography technique and etching technique. As a result, a groove h1, whose bottom is flush with Si substrate 1, is obtained. In this groove h1, a leg portion of a carrier is to be arranged. Note that the etching step in which the groove h1 is formed it is possible to stop etching at the surface of the Si substrate 1 or to overetch the Si substrate 1 so as to make the groove h1 deeper.

Then, a carrier film is formed over the entire surface of the Si substrate 1 in a way that the carrier film fills the groove h1. The carrier film is, for example, a silicon oxide (SiO₂) film having thickness of, for example, 400 [nm]. The carrier film is formed by using, for example, CVD method. Then, as shown in FIG. 3A and FIG. 3B, by using photolithography technique and etching technique, the carrier film is partially etched so that a carrier 22 is obtained, which covers the SiGe layer 15. After that, the respective parts of the SiGe layer 15, the Si layer 13, the SiGe layer 11 and the Si-buffer layer (not shown), which are exposed on the carrier 22, are successively etched so that a groove h2 that makes the respective lateral surfaces of the SiGe layer 15, the Si layer 13 and the SiGe layer 11, which are all covered by the carrier 22, to be exposed. In the etching step for forming the groove h2, it is possible to stop etching at the surface of the Si substrate 1 or to overetch the Si substrate 1 so as to make the groove h2 deeper.

Next, as indicated by arrows drawn in solid line in FIG. 4A and FIG. 4B, solution of fluorinated acid and nitric acid are brought into contact with the respective lateral surfaces of the SiGe layer 15, the Si layer 13 and the SiGe layer 11 so that the SiGe layer 15 and the SiGe layer 11 are selectively etched to be removed. As a result, as shown in FIGS. 4A and 4B, a first cavity 25 is formed between the Si substrate 1 and the Si layer 13, and at the same time, a second cavity 27 is formed between the Si layer 13 and the carrier 22. In the case of wet etching using solution of fluorinated acid and nitric acid, the etching rate of SiGe is higher than that of Si (in other words, the selection ratio of the etching for Si is larger). Therefore, it becomes possible to perform etching only to the SiGe layer 11, to be removed while the Si layer 13 is preserved. After the formation of the cavities 25, 27, the Si layer 13 is carried at its lateral surface by the carrier. As shown in FIG. 4B, after the formation of the cavities 25, 27, the upper and the lower structures relative to the Si layer 13 (in the vicinity of the Si layer 13) become substantially the same.

Next, as shown in FIG. 5A and FIG. 5B, the Si substrate is subjected to thermal oxidation, thereby forming thermally-oxidized films 31, 33 respectively in the first and the second cavities (BOX oxidation process). In the BOX oxidation process, it is possible to prevent the warpage in the Si layer 13 and to make no space left in the interface between the thermally-oxidized films 31a, 31b, which grow upwards and downwards in the cavity 25, respectively. Note that the thermally-oxidized films 31, 33 are both SiO₂ films since each of the upper and lower surfaces of the first and the second cavities are made from Si.

After the formation of the thermally-oxidized films 31, 33, an insulating layer is formed over the entire surface of the Si substrate 1 by using CVD method or the like so as to fill the grooves h1, h2. The insulating layer formed in this case is, for example, a SiO2 film or a silicon nitride (Si₃N₄) film. Then, the insulating layer covering the entire surface and the underlying carrier 22 are planarized by using, for example, a CMP technique. Note that in this CMP process the thermally-oxidized film 33 is suitably used as a stopper for the CMP treatment, thereby making it possible to prevent the surface of the Si layer 13 from being disadvantageously cut away. After that, the insulating layer and the thermally-oxidized film 33 after the CMP treatment are subjected to wet etching using, for example, BHF, thereby completely removing the thermally-oxidized film 33 from the surface of the Si layer 13. At this time, the interface of the thermally-oxidized film 31a and 31b closely adheres, so BHF is prevented from entering the interface. As described above, a SOI structure isolated from the surroundings by the carrier 22 and the insulating layer is fabricated on the Si substrate 1.

As described above, according to the embodiment of the invention, it is possible to prevent the warpage in the Si layer 13 at the time of formation of the thermally-oxidized layer 31 and to prevent space left in the interface between the thermally-oxidized layer 31a and the thermally-oxidized layer 31b. As a result, it becomes possible to prevent BHF from entering the above-mentioned interface at the time of performing etching to the carrier 22 and the insulating layer using BHF, thereby making it possible to preventing the Si layer 11 from coming off from the Si substrate 13.

According to the research of the inventors, the reason why such effects can be obtained is that in the BOX oxidization process the upper and lower structures relative to the Si layer 13 (in the vicinity of the Si layer 13) are substantially the same. It is deemed that during temperature ascending or descending period of the BOX oxidization the external force to be exerted from the thermally-oxidized film 31 onto the lower surface of the Si layer 13 and the external force to be exerted from the thermally-oxidized film 33 onto the upper surface of the Si layer 13 are almost balanced with each other, since the coefficients of thermal expansion of the thermally-oxidized films 31, 33 are substantially the same.

Further, it is deemed that the adhesion of the thermally-oxidized film 33 and the carrier 22 is not so high, since the thermally-oxidized film 33 grows from the Si layer 13 towards the carrier 22, so that the force involved in expansion or contract of the carrier is hardly to be transmitted to the Si layer 13.

According to this embodiment, Si substrate 1 corresponds to a “semiconductor substrate” according to the invention, the SiGe layer 11 corresponds to a “first semiconductor layer” according to the invention, the Si layer 13 corresponds to a “second semiconductor layer” according to the invention, and the SiGe layer 15 corresponds to a “third semiconductor layer” according to the invention. Further, the groove h1 corresponds to a “first groove” according to the invention, and the groove h2 corresponds to a “second groove” according to the invention. Furthermore, the cavity 25 corresponds to a “first cavity” according to the invention and the cavity 27 corresponds to a “second cavity” according to the invention. Moreover, the thermally-oxidized film 31 corresponds to a “first thermally-oxidized film” according to the invention, and the thermally-oxidized film 33 corresponds to a “second thermally-oxidized film” according to the invention.

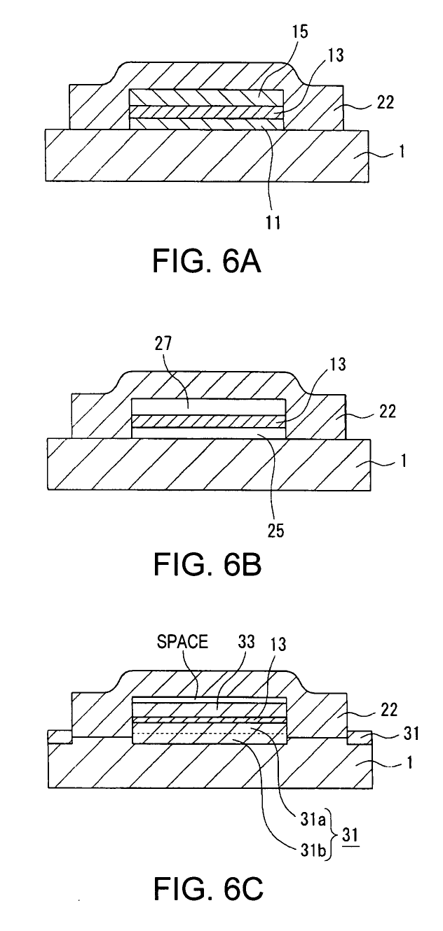

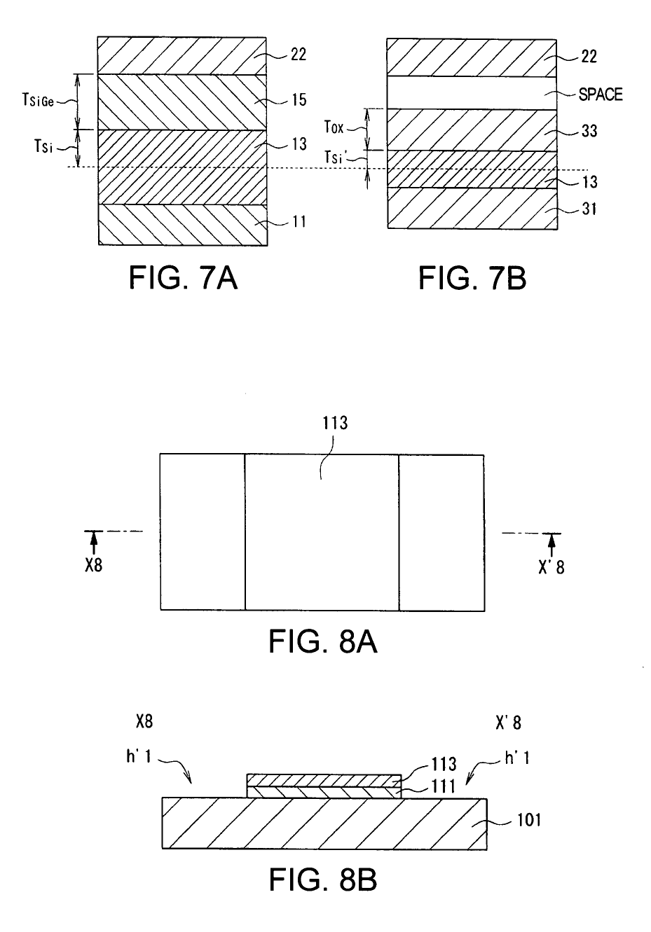

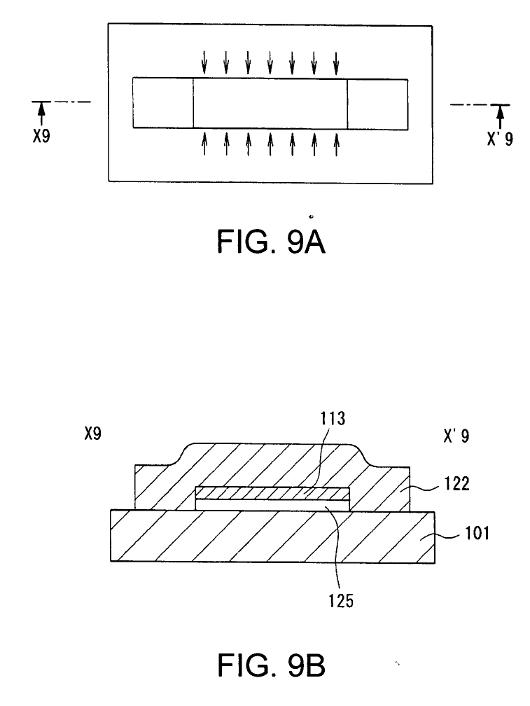

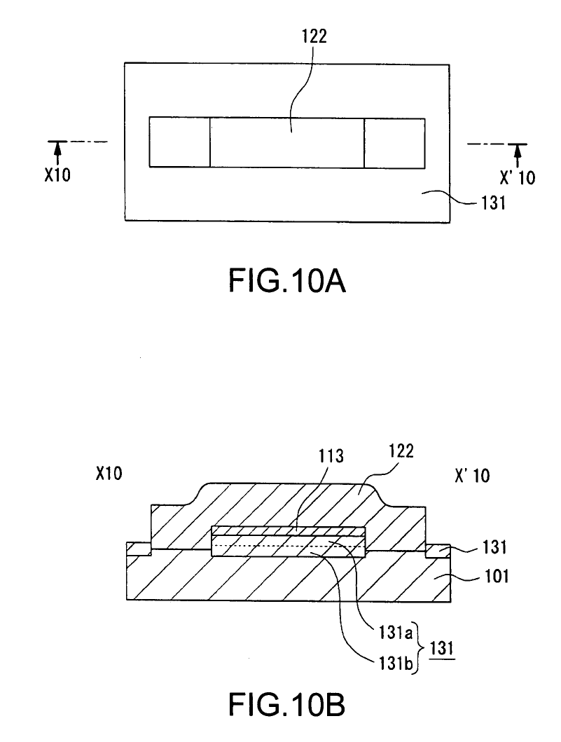

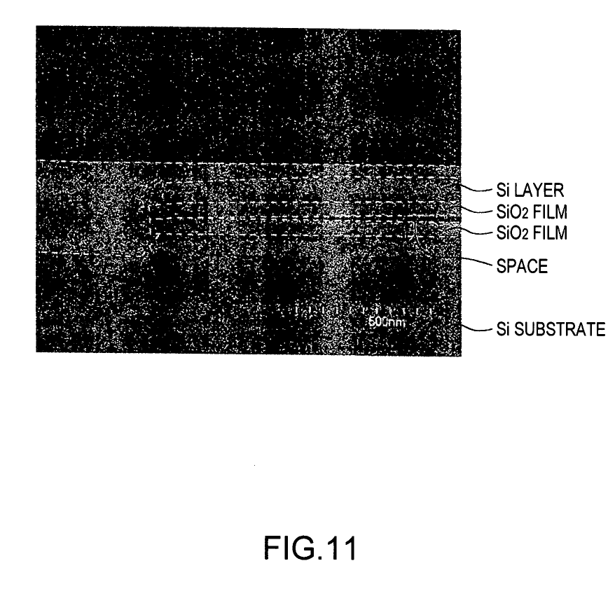

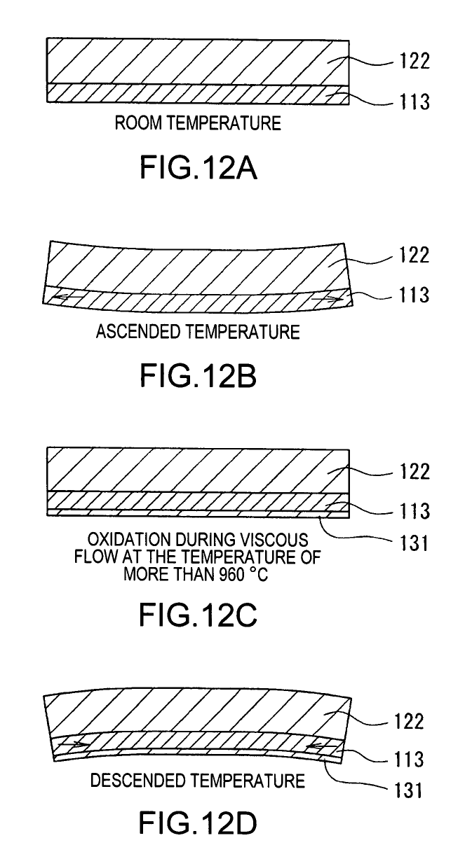

Note that as shown in FIG. 6A through FIG. 6C, according to this embodiment of the invention, the SiGe layer 15 may be formed to have thickness larger than necessary so that space can be preserved between the upper surface of the thermally-oxidized film 33 and the carrier 22 even after the formation of the thermally-oxidized films 31, 33. To be more specific, as shown in FIG. 7A, the thickness of the upper half of the Si layer 13 (from the center in its thickness direction) before the formation of the cavities 25, 27 is to be referred to as Tₛᵢ and the thickness of the SiGe layer 15 before the formation of the cavities 25, 27 is to be called T_{SiGe}, while the thickness of the upper half of the Si layer 13 (from the center in its thickness direction) after the formation of the cavities 25, 27 is to be referred to as Tₛᵢ′ and the thickness of the thermally-oxidized film 33 is to be called Tₒₓ. Then, in the step for forming the SiGe layer 15, the SiGe layer 15 is formed so thick as to fulfill the equation (1) below:
Tₛᵢ+T_{SiGe}>Tₛᵢ′+Tₒₓ (1)

In this way, space can be preserved between the upper surface of the thermally-oxidized film 33 and the carrier 22 throughout the BOX oxidation process. Therefore, the influence of expansion and contraction of the carrier 22 may be weakened through the intermediation of the space above described. As a result, it becomes possible to further suppress the warpage in the Si layer.

What is claimed is:

1. A method for manufacturing a semiconductor device, comprising:
a) successively staking on a semiconductor substrate a first semiconductor layer, a second semiconductor layer and a third semiconductor layer;
b) forming on the semiconductor substrate a first groove passing through the third semiconductor layer, the second semiconductor layer and the first semiconductor layer by partially etching the third semiconductor layer, the second semiconductor layer and the first semiconductor layer successively;
c) forming on the entire surface of the upper side of the semiconductor substrate a carrier film to fill the first groove and cover the third semiconductor layer;
d) exposing the third semiconductor layer by partially etching the carrier film including its site covering the third semiconductor layer;
e) forming a second groove by successively etching the third semiconductor layer, the second semiconductor layer and the first semiconductor layer, the etching starting from the exposed site of the third semiconductor layer in the step d);
f) forming a first cavity by etching the first semiconductor layer exposed on a lateral surface of the second groove;
g) forming a second cavity by etching the third semiconductor layer exposed on a lateral surface of the second groove; and
h) forming, by applying heat to the semiconductor substrate, a first thermally-oxidized film in the first cavity and a second thermally-oxidized film in the second cavity.

2. The method according to claim 1, wherein the step f) and the step g) are performed at the same time.

3. The method according to claim 1, further comprising:
i) depositing on the entire surface of the upper side of the semiconductor substrate an insulating layer after the formation of the first thermally-oxidized film and the second thermally-oxidized film; and
j) removing the insulating layer and the carrier film on the upper side of the semiconductor substrate by applying at least CMP treatment to the insulating layer, the second thermally-oxidized layer serving as a stopper for the CMP treatment.

4. The method according to claim 1, wherein the thickness of the third semiconductor layer formed in the first step is thicker than the thickness of the second thermally-oxidized film formed in the step h).

5. The method according to claim 1, wherein: the first semiconductor layer and the third semiconductor layer are each a single-crystal silicon germanium (SiGe) layer formed by using epitaxy; and the second semiconductor layer is a single-crystal silicon (Si) layer formed by using epitaxy.

6. A semiconductor device manufactured by the method for manufacturing a semiconductor device according to claim 1.
